(19) United States
(12) Patent Application Publication
(10) Pub. No.: US 2016/0365539 A1
(43) Pub. Date: Dec. 15, 2016

(54) ORGANIC LIGHT EMITTING DISPLAY DEVICE AND METHOD FOR PACKAGING ORGANIC LIGHT EMITTING DIODE

(71) Applicant: BOE TECHNOLOGY GROUP CO., LTD., Beijing (CN)

(72) Inventors: Chunjan WANG, Beijing (CN); Szuheng TSENG, Beijing (CN)

(73) Assignee: BOE TECHNOLOGY GROUP CO., LTD., Beijing (CN)

(21) Appl. No.: 14/771,352

(22) PCT Filed: Nov. 17, 2014
(86) PCT No.: PCT/CN2014/091247

§ 371 Date: Aug. 28, 2015

(30) Foreign Application Priority Data
Aug. 22, 2014 (CN) 201410419043.3

(51) Int. Cl. H01L 51/52; H01L 51/56; H01L 27/32

(52) U.S. Cl. CPC H01L 51/5253; H01L 27/3262; H01L 27/3276; H01L 51/56; H01L 27/3272

(57) ABSTRACT

The present disclosure provides an organic light emitting display device and a method for packaging an organic light emitting diode. The organic light emitting display device includes a lower substrate, a thin film transistor (TFT) function layer, an organic light emitting diode, a thin film packaging layer and an upper substrate which are arranged on the lower substrate. The thin film packaging layer includes at least one completely-covering layer. The completely-covering layer covers completely the lower substrate which is provided with the TFT function layer and the organic light emitting diode. The thin film packaging layer according to the present disclosure has advantageous such as having a good water-blocking effect, being of a simple structure, and being suitable for a flexible organic light emitting display device.

### CROSS-REFERENCE TO RELATED APPLICATION

The present application claims the priority of Chinese patent application No. 201410419043.3 filed on Aug. 22, 2014, the disclosure of which is incorporated herein by reference.

### TECHNICAL FIELD

The present disclosure relates to the field of an organic light emitting diode (OLED), in particular to an organic light emitting display device and a method for packaging an organic light emitting diode.

### BACKGROUND

An organic light emitting diode (OLED) device is easy to react with water and oxygen, which may attenuate characteristics of the device and generate black spots or dark area in a light emitting region, thereby affecting performance of the device. Therefore, after completion of manufacturing of the OLED device, the OLED device needs to be packaged by a packaging structure.

Referring to FIG. 1, which is a schematic diagram showing a structure of an organic light emitting display device in the related art, the organic light emitting display device includes a lower substrate 101 provided with a thin film transistor (TFT) function layer, an organic light emitting diode 103, a cover 104, a water-blocking sealant 105 for sealing the lower substrate 101 and the cover 104, and moisture absorption material 106 arranged on a side of the cover 104. However, such packaging structure is difficult to be used in a top-emission OLED device, and has a complex structure.

FIG. 2 is a schematic diagram showing a structure of another organic light emitting display device in the related art. The organic light emitting display device includes a lower substrate 101 provided with a TFT function layer, an organic light emitting diode 103, a cover 104 and glass cement material 107 for sealing the lower substrate 101 and the cover 104. Such packaging structure can be used in the top-emission OLED device. However, it cannot be used in a flexible OLED device due to large hardness of the glass cement material.

### SUMMARY

In view of this, the present disclosure provides an organic light emitting display device. The organic light emitting display device is of a simple structure and suitable for a flexible organic light emitting display device.

In order to solve the above technical problems, the present disclosure provides an organic light emitting display device, including: a lower substrate, and a thin film transistor (TFT) function layer, an organic light emitting diode, a thin film packaging layer and an upper substrate which are arranged on the lower substrate. The thin film packaging layer includes at least one completely-covering layer, the completely-covering layer covers completely the lower substrate which is provided with the TFT function layer and the organic light emitting diode.

Alternatively, a total thickness of the at least one completely-covering layer is less than a predetermined threshold value.

Alternatively, the predetermined threshold value is 100 nm.

Alternatively, the completely-covering layer is made of a water-blocking material.

Alternatively, the water-blocking material is metal oxide or metal nitride.

Alternatively, the thin film packaging layer further includes at least one packaging strengthening layer, which is only arranged above a region where the organic light emitting diode is located.

Alternatively, the upper substrate covers a region on the lower substrate except for a circuit connecting region of the TFT function layer.

Alternatively, the thin film packaging layer includes one completely-covering layer and two packaging strengthening layers. The completely-covering layer is a first layer of the thin film packaging layer and is positioned between the organic light emitting diode and the two packaging strengthening layers.

Alternatively, the thin film packaging layer includes one completely-covering layer and two packaging strengthening layers. The completely-covering layer is positioned between the two packaging strengthening layers and covers completely the lower substrate which is provided with the packaging strengthening layers, the TFT function layer and the organic light emitting diode.

Alternatively, the thin film packaging layer includes two completely-covering layers. One of the two completely-covering layers is a first layer of the thin film packaging layer, positioned between the organic light emitting diode and the two packaging strengthening layers, and covers completely the lower substrate which is provided with the TFT function layer and the organic light emitting diode; the other of the two completely-covering layers is positioned between the two packaging strengthening layers and covers completely the lower substrate which is provided with one packaging strengthening layer, the TFT function layer and the organic light emitting diode.

On another aspect, the present disclosure further provides a method for packaging an organic light emitting diode. The method for packaging the organic light emitting diode is simple and can be used on the flexible organic light emitting display device. The method includes steps of:

forming a thin film transistor (TFT) function layer on a lower substrate;

forming an organic light emitting diode on the lower substrate on which the TFT function layer is formed;

forming a thin film packaging layer on the lower substrate on which the organic light emitting diode is formed, in such as manner that the thin film packaging layer includes at least one completely-covering layer and the completely-covering layer covers completely the lower substrate which is provided with the TFT function layer and the organic light emitting diode;

covering the lower substrate on which the thin film packaging layer is formed with an upper substrate.

Alternatively, the completely-covering layer is formed by a film coating method.

Alternatively, the film coating method is a thermal evaporation method, an atomic layer deposition method, a chemical vapor deposition method, or a physical vapor deposition method.

Alternatively, the thin film packaging layer further includes at least one packaging strengthening layer, which is only arranged above a region where the organic light emitting diode is located, the packaging strengthening layer is formed by following steps:

placing a mask plate above the lower substrate on which other layers has been formed, in such a manner that the mask plate is provided with hollow patterns and the hollow patterns correspond to the region where the organic light emitting diode is located;

coating packaging material for preparing the packaging strengthening layer on the mask plate; and

removing the mask plate with the packaging material corresponding to the hollow patterns remained on the lower substrate to form patterns of the packaging strengthening layer.

Alternatively, the thin film packaging layer includes one completely-covering layer and two packaging strengthening layers, the completely-covering layer is a first layer of the thin film packaging layer and positioned between the organic light emitting diode and the two packaging strengthening layers.

Alternatively, the thin film packaging layer includes one completely-covering layer and two packaging strengthening layers; the completely-covering layer is positioned between the two packaging strengthening layers and covers completely the lower substrate which is provided with the packaging strengthening layers, the TFT function layer and the organic light emitting diode.

Alternatively, the thin film packaging layer includes two completely-covering layers. One of the two completely-covering layers is a first layer of the thin film packaging layer, positioned between the organic light emitting diode and the two packaging strengthening layers, and covers completely the lower substrate which is provided with the TFT function layer and the organic light emitting diode; the other of the two completely-covering layers is positioned between the two packaging strengthening layers and covers completely the lower substrate which is provided with one packaging strengthening layer, the TFT function layer and the organic light emitting diode.

The beneficial effects of the above technical solutions of the present disclosure are as follows.

The completely-covering layer is a whole-layer thin film structure and able to completely cover the lower substrate which is provided with the TFT function layer and the organic light emitting diode. Therefore, the sealing effect is better, and the completely-covering layer which is a whole-layer thin film structure can be formed by a film coating process, and does not require an exposing process to form patterns, thereby avoiding damages to the organic light emitting diode caused by the exposing process.

### BRIEF DESCRIPTION OF THE DRAWINGS

FIG. 1 is a schematic diagram showing a structure of an organic light emitting display device in the related art;

FIG. 2 is a schematic diagram showing a structure of another organic light emitting display device in the related art;

FIG. 3 is a schematic diagram showing a structure of an organic light emitting display device according to a first embodiment of the present disclosure;

FIG. 4 is a schematic diagram showing a structure of an organic light emitting display device according to a second embodiment of the present disclosure;

FIG. 5 is a schematic diagram showing a structure of an organic light emitting display device according to a third embodiment of the present disclosure; and

FIG. 6 is a schematic diagram showing a structure of an organic light emitting display device according to a fourth embodiment of the present disclosure.

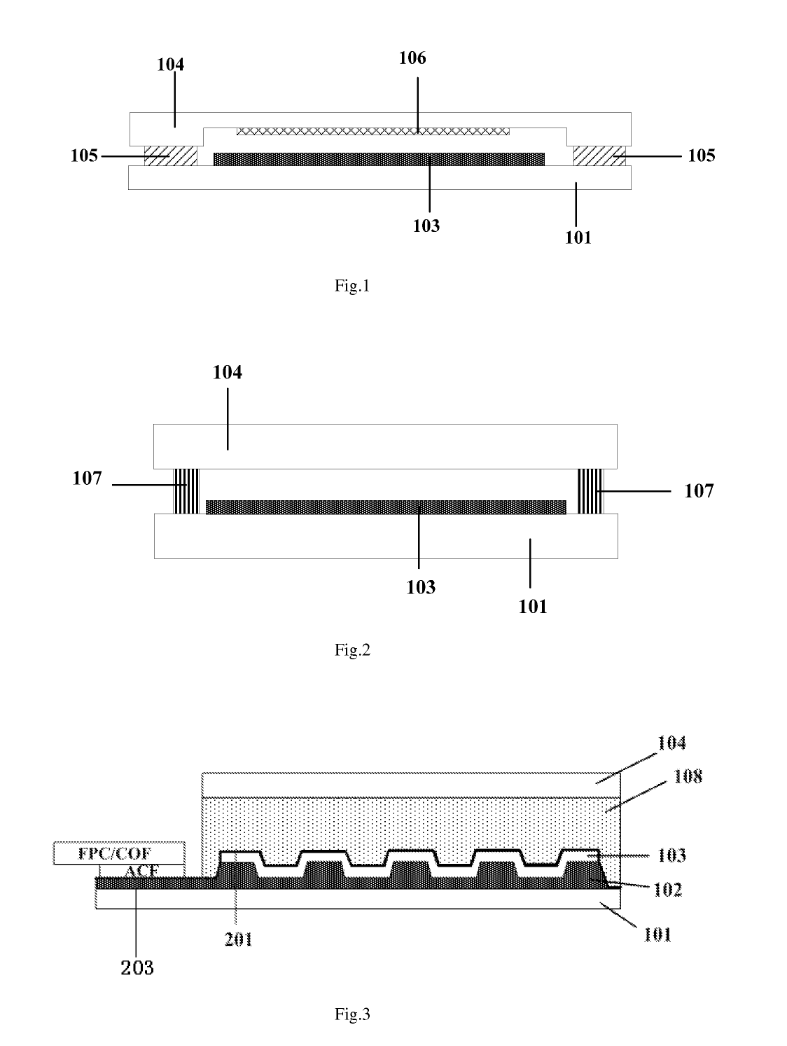

### DETAILED DESCRIPTION

In order to make the technical problems to be solved, the technical solutions and advantages of the present disclosure more clear, a detailed description will be given hereinafter in conjunction with the accompanying drawings and embodiments of the present disclosure.

Referring to FIG. 3, which is a schematic diagram showing a structure of an organic light emitting display device according to a first embodiment of the present disclosure, the organic light emitting display device includes a lower substrate 101, and a thin film transistor (TFT) function layer 102, an organic light emitting diode 103, a thin film packaging layer and an upper substrate 104 which are sequentially arranged on the lower substrate 101. The thin film packaging layer includes at least one completely-covering layer 201 (the accompanying drawing of this embodiment shows only one completely-covering layer 201). The completely-covering layer 201 covers completely the lower substrate 101 which is provided with the TFT function layer 102 and the organic light emitting diode 103.

The upper substrate 104 and the lower substrate 101 can be made of materials such as glass, plastic or metals.

The TFT function layer 102 may include a gate electrode, a gate insulating layer, an active layer, source and drain electrodes and a passivation layer and the like.

The organic light emitting diode 103 may include an upper electrode, an organic light emitting layer and a lower electrode. The lower electrode is connected to the drain electrode of the TFT function layer 102.

The completely-covering layer 201 is made of a water-blocking material. The water-blocking material may be metal oxide or metal nitride. The metal oxide includes, but not limited to, Al₂O₃, ZrO₂ and TiO₂. The metal nitride includes, but not limited to, AlN, Mg₃N₂ and TiN.

The completely-covering layer 201 is a whole-layer thin film structure, and able to cover completely the lower substrate 101 which is provided with the TFT function layer 102 and the organic light emitting diode 103. Therefore, the sealing effect is better, and the completely-covering layer 201 which is a whole-layer thin film structure can be formed by a film coating process, which does not require for an exposing process to form a pattern, thereby avoiding damages to the organic light emitting diode 103 caused by the exposing process.

The film coating method may be any one of a thermal evaporation method, an atomic layer deposition (ALD) method, a chemical vapor deposition (CVD) method, or a physical vapor deposition (PVD) method.

The above TFT function layer 102 needs to be connected to an external circuit board (such as a flexible print circuit (FPC) board or chip on film (COF)) so as to receive an electrical signal. Therefore, in general, a circuit connecting region 203 is provided on the TFT function layer 102, and the external circuit board is fixed on the circuit connecting region by anisotropic conductive film (ACF) and electrically connected to the TFT function layer 102. In this embodiment, since the completely-covering layer 201 covers completely the lower substrate 101, that is, in addition to covering the organic light emitting diode 103, the completely-covering layer 201 further covers the circuit connecting region of the TFT function layer 102. In order to ensure that the TFT function layer 102 and the external circuit board are connected normally, in one embodiment of the present disclosure, a total thickness of the at least one completely-covering layer 201 is less than a predetermined threshold value so that conductive particles through the ACF can penetrate the at least one completely-covering layer 201, so as to ensure that the TFT function layer and the external circuit can be normally connected in the circuit connecting region. The predetermined threshold value may be 100 nm.

In addition, the upper substrate 104 covers a region on the lower substrate 101 except for the circuit connecting region 203 of the TFT function layer 102. The circuit connecting region 203 of the TFT function layer 102 is not covered by the upper substrate 104, so as to ensure an exposure of the circuit connecting region.

The upper substrate 104 is adhered to the lower substrate 101 by a sealant 108.

In order to further improving the packaging performance, the thin film packaging layer may further include at least one packaging strengthening layer, which is only arranged above a region where the organic light emitting diode 103 is located. That is, the packaging strengthening layer does not cover the circuit connecting region 203 of the TFT function layer 102 so as to ensure an exposure of the circuit connecting region, thereby ensuring a normal connection between the TFT function layer 102 and the external circuit board.

As mentioned above, after the completion of manufacturing of the organic light emitting diode 103, an exposing process cannot be used in the sequential process. Therefore, when preparing patterns of the packaging strengthening layer, an exposing process cannot be used either. In one embodiment of the present disclosure, the packaging strengthening layer can be formed by the following steps.

First, a mask plate is placed above the lower substrate 101 on which other layers has been formed. The mask plate is provided with hollow patterns and the hollow patterns correspond to the region where the organic light emitting diode 103 is located. The other layers may include the TFT function layer 102 and the organic light emitting diode 103. In some embodiments, the other layers may further include the completely-covering layer 201.

Then, a packaging material for preparing the packaging strengthening layer is coated on the mask plate.

Finally, the mask plate is removed. The packaging material corresponding to the hollow patterns is remained on the lower substrate to form patterns of the packaging strengthening layer.

The packaging material for preparing the packaging strengthening layer may be an organic material, an inorganic material or an organic/inorganic mixed material. The organic material includes, but not limited to, Polymethyl methacrylate (PMMA), dimethyl siloxane, methyl phenyl siloxane, diphenyl siloxane and silicone resin and the like. The inorganic material includes, but not limited to, silicon dioxide and silicon nitride and the like.

Both of the completely-covering layer and the packaging strengthening layer in the above thin film packaging layer are not made of rigid material. Therefore, the thin film packaging layer according to the embodiment of the present disclosure has features such as being light, thin and flexible and is suitable for the flexible organic light emitting display device.

The completely-covering layer and the packaging strengthening layer in the above thin film packaging layer may be of a lot of different structures, which will be described hereinafter.

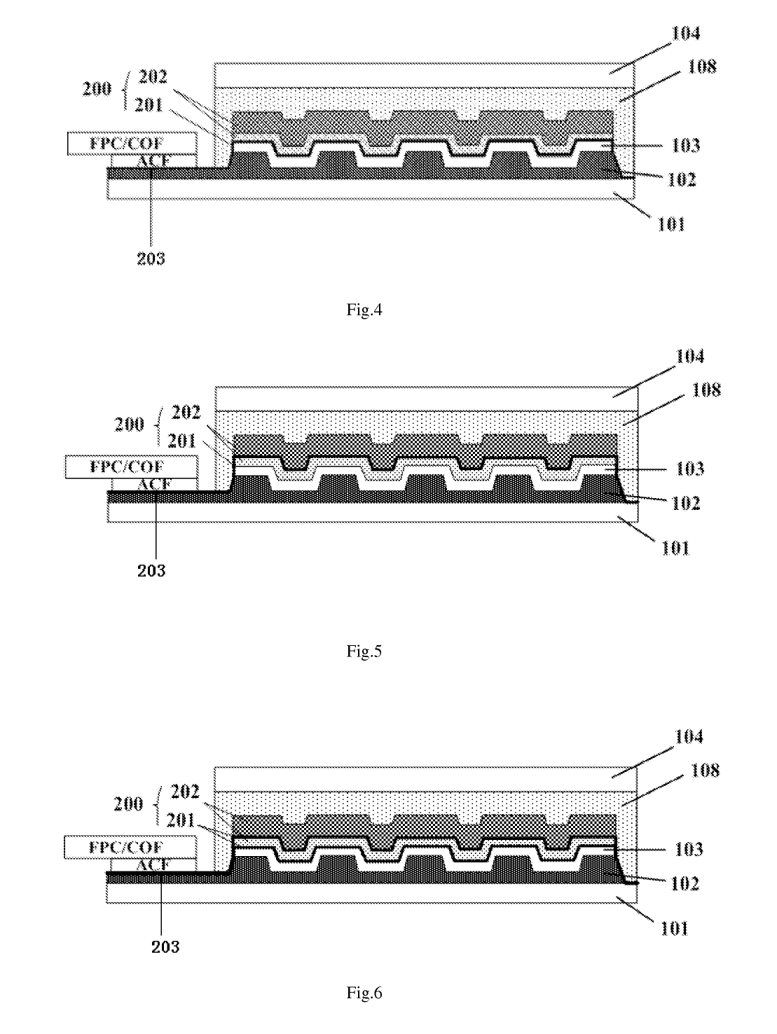

Referring to FIG. 4, which is a schematic diagram showing a structure of an organic light emitting display device according to a second embodiment of the present disclosure, the organic light emitting display device includes a lower substrate 101, and a TFT function layer 102, an organic light emitting diode 103, a thin film packaging layer 200 and an upper substrate 104 which are sequentially arranged on the lower substrate 101. The thin film packaging layer 200 may include one completely-covering layer 201 and two packaging strengthening layers 202. The completely-covering layer 201 covers completely the lower substrate 101 which is provided with the TFT function layer 102 and the organic light emitting diode 103. The two packaging strengthening layers 202 only cover a region where the organic light emitting diode 103 is located, and do not cover a circuit connecting region 203 of the TFT function layer 102. The upper substrate 104 is arranged above the thin film packaging layer 200 and does not cover the circuit connecting region 203 of the TFT function layer 102. The upper substrate 104 is adhered to the lower substrate 101 by a sealant 108.

In one embodiment, the completely-covering layer 201 is a first layer of the thin film packaging layer 200, that is, the completely-covering layer 201 is positioned between the packaging strengthening layer 202 and the organic light emitting diode 103.

Referring to FIG. 5, which is a schematic diagram showing a structure of an organic light emitting display device according to a third embodiment of the present disclosure, this embodiment is different from the embodiment shown in FIG. 4 in that the completely-covering layer 201 is a middle layer of the thin film packaging layer, i.e., positioned between two packaging strengthening layers 202.

Referring to FIG. 6, which is a schematic diagram showing a structure of an organic light emitting display device according to a fourth embodiment of the present disclosure, this embodiment is different from the embodiment shown in FIG. 4 in that the thin film packaging layer includes two completely-covering layers 201, one of which is a first layer of the thin film packaging layer 200 and the other of which is a middle layer of the thin film packaging layer 200, i.e., positioned between two packaging strengthening layers 202.

The organic light emitting display device in the above embodiments may be an OLED display device or an OLED illumination device.

The present disclosure further provides in one embodiment a method for packaging an organic light emitting diode, including following steps.

At Step S1, forming a thin film transistor (TFT) function layer on a lower substrate.

At Step S2, forming an organic light emitting diode on the lower substrate on which the TFT function layer is formed.

At Step S3, forming a thin film packaging layer on the lower substrate on which the organic light emitting diode is formed, in such a manner that the thin film packaging layer includes at least one completely-covering layer and the completely-covering layer covers completely the lower substrate on which the TFT function layer and the organic light emitting diode are formed.

At Step S4, covering the lower substrate on which the thin film packaging layer is formed with an upper substrate.

The completely-covering layer may be formed by a film coating method and does not require an exposing process to form patterns, thus damages on the organic light emitting diode caused by the exposing process can be avoided.

The film coating method may be a thermal evaporation method, an atomic layer deposition (ALD) method, a chemical vapor deposition (CVD) method, or a physical vapor deposition (PVD) method.

The thin film packaging layer may further include at least one packaging strengthening layer, which is only arranged above the region where the organic light emitting diode is located. The packaging strengthening layer can be formed by the following steps.

A mask plate is placed above the lower substrate on which other layers has been formed. The mask plate is provided with hollow patterns and the hollow patterns correspond to the region where the organic light emitting diode is located.

Packaging material for preparing the packaging strengthening layer is coated on the mask plate.

The mask plate is removed. The packaging material corresponding to the hollow patterns is remained on the lower substrate to form patterns of the packaging strengthening layer.

The packaging strengthening layer can improve the packaging performance of the thin film packaging layer. In addition, when preparing patterns of the packaging strengthening layer, the exposing process is not required, thereby avoiding damages to the organic light emitting diode.

The above is only optional embodiments of the present disclosure, it should be noted that several improvements and modifications may be made for a person skilled in the art without departing from the principle of the present disclosure, and also should be considered to fall within the protection scope of the present disclosure.

What is claimed is:

1. An organic light emitting display device, comprising:
a lower substrate, and a thin film transistor (TFT) function layer, an organic light emitting diode, a thin film packaging layer and an upper substrate which are arranged on the lower substrate;
wherein the thin film packaging layer comprises at least one completely-covering layer; the completely-covering layer covers completely the lower substrate which is provided with the TFT function layer and the organic light emitting diode.

2. The organic light emitting display device according to claim 1, wherein a total thickness of the at least one completely-covering layer is less than a predetermined threshold value.

3. The organic light emitting display device according to claim 2, wherein the predetermined threshold value is 100 nm.

4. The organic light emitting display device according to claim 1, wherein the completely-covering layer is made of a water-blocking material.

5. The organic light emitting display device according to claim 4, wherein the water-blocking material is metal oxide or metal nitride.

6. The organic light emitting display device according to claim 1, wherein the thin film packaging layer further comprises:
at least one packaging strengthening layer which is only arranged above a region where the organic light emitting diode is located.

7. The organic light emitting display device according to claim 1, wherein the upper substrate covers a region on the lower substrate except for a circuit connecting region of the TFT function layer.

8. The organic light emitting display device according to claim 6, wherein the thin film packaging layer comprises one completely-covering layer and two packaging strengthening layers; the completely-covering layer is a first layer of the thin film packaging layer and is positioned between the organic light emitting diode and the two packaging strengthening layers.

9. The organic light emitting display device according to claim 6, wherein the thin film packaging layer comprises one completely-covering layer and two packaging strengthening layers; the completely-covering layer is positioned between the two packaging strengthening layers and covers completely the lower substrate which is provided with the packaging strengthening layers, the TFT function layer and the organic light emitting diode.

10. The organic light emitting display device according to claim 6, wherein the thin film packaging layer comprises two completely-covering layers; one of the two completely-covering layers is a first layer of the thin film packaging layer, positioned between the organic light emitting diode and the two packaging strengthening layers, and covers completely the lower substrate which is provided with the TFT function layer and the organic light emitting diode; the other of the two packaging strengthening layers is positioned between the two packaging strengthening layers and covers completely the lower substrate which is provided with one packaging strengthening layer, the TFT function layer and the organic light emitting diode.

11. A method for packaging an organic light emitting diode, comprising steps of:
forming a thin film transistor (TFT) function layer on a lower substrate;
forming an organic light emitting diode on the lower substrate on which the TFT function layer is formed;
forming a thin film packaging layer on the lower substrate on which the organic light emitting diode is formed, in such a manner that the thin film packaging layer comprises at least one completely-covering layer and the completely-covering layer covers completely the lower substrate which is provided with the TFT function layer and the organic light emitting diode;
covering the lower substrate on which the thin film packaging layer is formed with an upper substrate.

12. The method according to claim 11, wherein the completely-covering layer is formed by a film coating method.

13. The method according to claim 12, wherein the film coating method is a thermal evaporation method, an atomic layer deposition method, a chemical vapor deposition method, or a physical vapor deposition method.

14. The method according to claim 11, wherein the thin film packaging layer further comprises at least one packaging strengthening layer which is only arranged above a region where the organic light emitting diode is located, the packaging strengthening layer is formed by following steps:
placing a mask plate above the lower substrate on which other layers have been formed, in such a manner that the mask plate is provided with hollow patterns and the hollow patterns correspond to a region where the organic light emitting diode is located;
coating packaging material for preparing the packaging strengthening layer on the mask plate; and
removing the mask plate with the packaging material corresponding to the hollow patterns remained on the lower substrate to form patterns of the packaging strengthening layer.

15. The method according to claim 11, wherein the thin film packaging layer comprises one completely-covering layer and two packaging strengthening layers; the completely-covering layer is a first layer of the thin film packaging layer and positioned between the organic light emitting diode and the two packaging strengthening layers.

16. The method according to claim 11, wherein the thin film packaging layer comprises one completely-covering layer and two packaging strengthening layers; the completely-covering layer is positioned between the two packaging strengthening layers; the completely-covering layer covers completely the lower substrate which is provided with the packaging strengthening layers, the TFT function layer and the organic light emitting diode.

17. The method according to claim 11, wherein the thin film packaging layer comprises two completely-covering layers; one of the two completely-covering layers is a first layer of the thin film packaging layer, positioned between the organic light emitting diode and the two packaging strengthening layers and covers completely the lower substrate which is provided with the TFT function layer and the organic light emitting diode; the other of the two completely-covering layers is positioned between the two packaging strengthening layers and covers completely the lower substrate which is provided with one packaging strengthening layer, the TFT function layer and the organic light emitting diode.
